(19) United States
(12) Patent Application Publication
(10) Pub. No.: US 2025/0215571 A1
(43) Pub. Date: Jul. 3, 2025

(54) METHOD TO TREAT CARBON NANOTUBE FILM SURFACE

(71) Applicants: Tsinghua University, Beijing (CN); HON HAI PRECISION INDUSTRY CO., LTD., New Taipei (TW)

(72) Inventors: LIANG LIANG, Beijing (CN); YANG WEI, Beijing (CN); SHOU-SHAN FAN, Beijing (CN)

(21) Appl. No.: 18/978,228

(22) Filed: Dec. 12, 2024

(30) Foreign Application Priority Data
Dec. 27, 2023 (CN) 202311824832.0

(51) Int. Cl. C23C 16/56; C23C 16/26

(52) U.S. Cl. CPC C23C 16/56; C23C 16/26

(57) ABSTRACT

A method to treat carbon nanotube film surface, comprises: S1: providing a carbon nanotube film, and laying the carbon nanotube film on a surface of a substrate, wherein the carbon nanotube film comprises a plurality of catalyst particles; S2: annealing the carbon nanotube film; S3: treating the carbon nanotube film with an inorganic acid, and the plurality of metal catalyst particles in the carbon nanotube film react with the inorganic acid to generate inorganic salts; and S4: washing and annealing the carbon nanotube film with the inorganic salts to remove the inorganic salts.

### CROSS-REFERENCE TO RELATED APPLICATIONS

This application claims all benefits accruing under 35 U.S.C. § 119 from China Patent Application No. 202311824832.0, filed on Dec. 27, 2023, in the China National Intellectual Property Administration, the contents of which are hereby incorporated by reference.

### FIELD

The disclosure relates to a method to treat carbon nanotube film surface.

### BACKGROUND

Carbon nanotubes have a broad application prospect due to their unique structure and excellent mechanical, electrical and chemical properties. They have attracted great amount of attention from many scientists in the fields of materials, physics, electronics, chemistry, etc., and have become the research frontier and hotspot in the field of new materials. Carbon nanotube films containing multiple carbon nanotubes have also been applied to various fields. For example, carbon nanotube films are applied to grow epitaxial structures. It adopts the method of laying a carbon nanotube film on a substrate, and then epitaxially growing gallium nitride on the carbon nanotube film. However, since the carbon nanotube film is obtained by carbon nanotube arrays, and the carbon nanotube arrays are generally grown by chemical vapor deposition (CVD), a process that catalysts are deposited on silicon substrates to grow carbon nanotube arrays. So carbon nanotube films grown by the CVD method generally have metal catalyst particles in the carbon nanotubes of the carbon nanotube film, the metal catalyst particles affect the quality of gallium nitride. The application of carbon nanotube films containing metal catalyst particles will also affect the quality and performance of the application in the other fields.

### BRIEF DESCRIPTION OF THE DRAWINGS

Implementations of the present technology will now be described, by way of example only, with reference to the attached FIG.s, wherein:

FIG. 1 is a flow chart of an embodiment of a method to treat carbon nanotube film surface described in the present disclosure

FIG. 2 is a scanning electron microscope photo of a single-layer super-aligned carbon nanotube film made by the method shown in FIG. 1.

FIG. 3 is a schematic diagram of the structure of carbon nanotube fragments in a single-layer super-aligned carbon nanotube film made by the method shown in FIG. 1.

FIG. 4 is a scanning electron microscope photo of a carbon nanotube flocculated film made by the method shown in FIG. 1.

FIG. 5 is a scanning electron microscope photo of a carbon nanotube pressed film made by the method shown in FIG. 1.

### DETAILED DESCRIPTION

The disclosure is illustrated by way of example and not by way of limitation in the FIG.s of the accompanying drawings in which like references indicate similar elements. It should be noted that references to “another,” “an,” or “one” embodiment in this disclosure are not necessarily to the same embodiment, and such references mean “at least one.”

It will be appreciated that for simplicity and clarity of illustration, where appropriate, reference numerals have been repeated among the different FIG.s to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts have been exaggerated to illustrate details and features of the present disclosure better.

Several definitions that apply throughout this disclosure will now be presented.

The term “substantially” is defined to be essentially conforming to the particular dimension, shape, or other feature which is described, such that the component need not be exactly or strictly conforming to such a feature. The term “comprise,” when utilized, means “comprise, but not necessarily limited to”; it specifically indicates open-ended inclusion or membership in the so-described combination, group, series, and the like. The term of “first”, “second” and the like, are only used for description purposes, and should not be understood as indicating or implying their relative importance or implying the number of indicated technical features. Thus, the features defined as “first”, “second” and the like expressly or implicitly comprise at least one of the features. The term of “multiple times” means at least two times, such as two times, three times, etc., unless otherwise expressly and specifically defined.

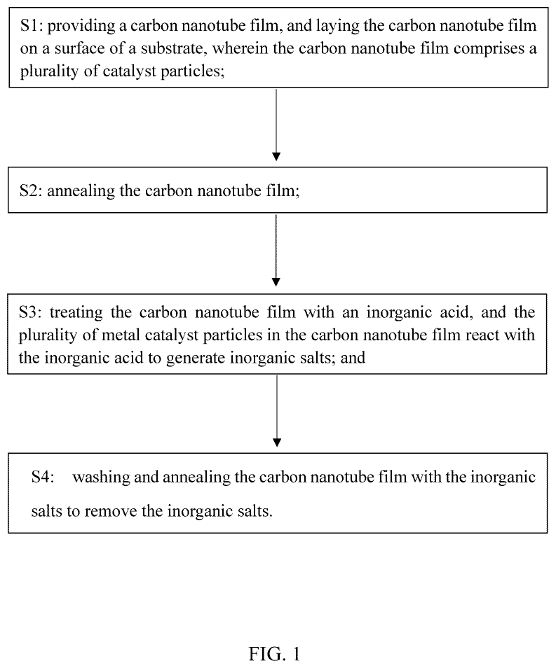

The present invention provides a method to treat carbon nanotube film surface. The method to treat carbon nanotube film is configured to remove metal catalyst particles in the carbon nanotube film. Please refer to FIG. 1, the method to treat carbon nanotube film surface comprises the following steps:
S1: providing a carbon nanotube film, and laying the carbon nanotube film on a surface of a substrate, wherein the carbon nanotube film comprises a plurality of catalyst particles;
S2: annealing the carbon nanotube film;
S3: treating the carbon nanotube film with an inorganic acid, and the plurality of metal catalyst particles in the carbon nanotube film react with the inorganic acid to generate inorganic salts; and
S4: washing and annealing the carbon nanotube film with the inorganic salts to remove the inorganic salts.

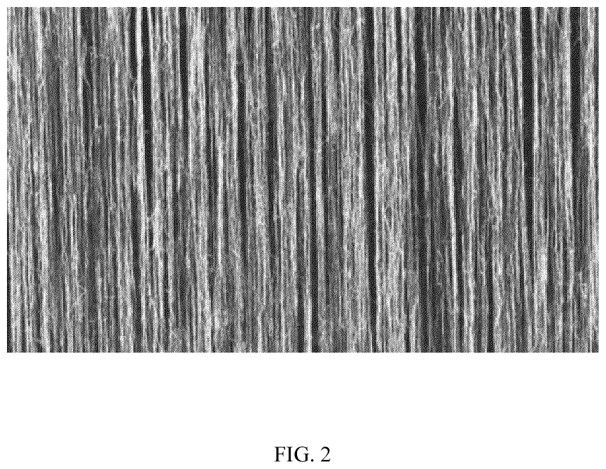

In step S1, at least one layer of carbon nanotube film is laid on a cleaned substrate. The substrate can be selected from sapphire, silicon wafer, silicon oxide wafer, etc. If the carbon nanotube film is too thick, it is not conducive to subsequent acid treatment and cleaning, so a carbon nanotube film of a reasonable thickness can be selected for surface treatment. Then, a volatile organic solvent such as ethanol, acetone, isopropanol, etc. is used to shrink the carbon nanotube film and dry it at 50-80° C. In one embodiment, it is preferred to lay 6 layers of super-aligned carbon nanotube film on a silicon oxide substrate. The super-aligned carbon nanotube film is a carbon nanotube film obtained by pulling from a carbon nanotube array. Please refer to FIG. 2, the super-aligned carbon nanotube film comprises a plurality of carbon nanotubes preferentially oriented in the same direction and arranged parallel to the surface of the super-aligned carbon nanotube film, and the plurality of carbon nanotubes are connected end to end by van der Waals forces.

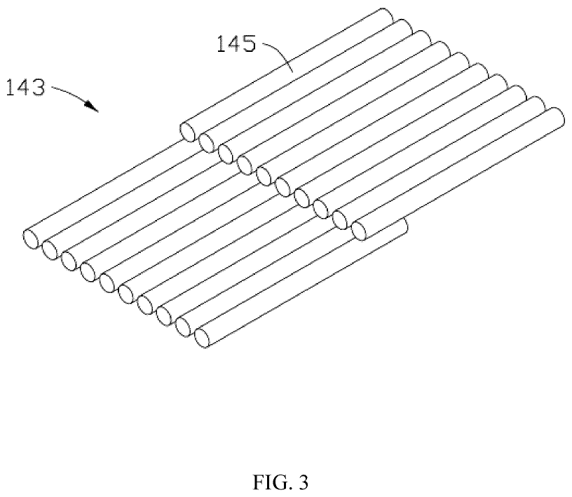

Please also refer to FIG. 3, each super-aligned carbon nanotube film comprises a plurality of continuous and directional carbon nanotube segments 143. The plurality of carbon nanotube segments 143 are connected end to end by van der Waals forces. Each carbon nanotube segment 143 comprises a plurality of mutually parallel carbon nanotubes 145, and the plurality of mutually parallel carbon nanotubes 145 are tightly connected by van der Waals forces. The carbon nanotube segment 143 has an arbitrary width, thickness, uniformity and shape. The thickness of the super-aligned carbon nanotube film is 0.5 nanometers to 100 microns, and the width is related to the size of the carbon nanotube array from which the super-aligned carbon nanotube film is drawn, and the length is not limited. On the substrate, the multi-layer super-aligned carbon nanotube film is superimposed on each other, and the preferred orientation of the carbon nanotubes in the adjacent two layers of super-aligned carbon nanotube film forms a cross angle α, α is greater than or equal to 0 degrees and less than or equal to 90 degrees (0°≤β≤90°).

In this embodiment, the 6 layers of super-aligned carbon nanotube films are orthogonally laid on a silicon oxide substrate, that is, the extension directions of the preferentially oriented carbon nanotubes in two adjacent layers of the 6 layers of super-aligned carbon nanotube films are perpendicular to each other. Then, the super-aligned carbon nanotube film is shrunk using an ethanol solvent and dried at 60° C.

It can be understood that the carbon nanotube film is not limited to the super-aligned carbon nanotube film in this embodiment, and can also be a carbon nanotube pressed film and a carbon nanotube flocculation film. Of course, the carbon nanotube film is not limited to these carbon nanotube films.

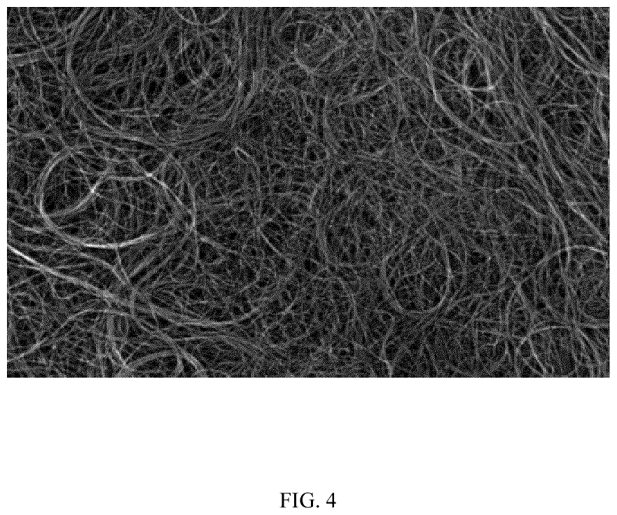

The carbon nanotube flocculation film is a carbon nanotube film formed by a flocculation method, and the carbon nanotube flocculation film comprises carbon nanotubes that are entangled and evenly distributed. The length of the carbon nanotube is greater than 10 microns, preferably 200 to 900 microns. The carbon nanotubes are attracted and entangled with each other by van der Waals forces to form a network structure. The carbon nanotube flocculation film is isotropic. The carbon nanotubes in the carbon nanotube flocculated film are evenly distributed and arranged irregularly, forming a large number of pore structures with a pore size of less than about 10 microns. The length and width of the carbon nanotube flocculated film are not limited. Please refer to FIG. 4. Since the carbon nanotubes are entangled with each other in the carbon nanotube flocculated film, the carbon nanotube flocculated film has good flexibility and is a self-supporting structure that can be bent and folded into any shape without breaking.

The carbon nanotube pressed film is a carbon nanotube film formed by rolling a carbon nanotube array. The carbon nanotube pressed film comprises uniformly distributed carbon nanotubes, which are preferentially oriented and arranged in the same direction or in different directions. The carbon nanotubes can also be isotropic. The carbon nanotubes in the carbon nanotube pressed film partially overlap each other, and attract each other through van der Waals force and are tightly combined, so that the carbon nanotube layer has good flexibility and can be bent and folded into any shape without breaking. And because the carbon nanotubes in the carbon nanotube pressed film attract each other through van der Waals force and are tightly combined, the carbon nanotube pressed film is a self-supporting structure.

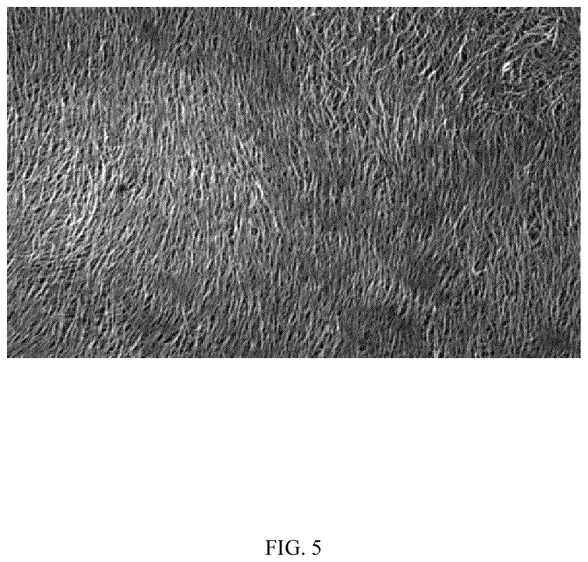

The carbon nanotube pressed film can be obtained by rolling a carbon nanotube array. The carbon nanotubes in the carbon nanotube pressed film form an angle β with the surface of the growth substrate forming the carbon nanotube array, wherein β is greater than or equal to 0 degrees and less than or equal to 15 degrees (0≤β≤15°), and the angle β is related to the pressure applied to the carbon nanotube array. The greater the pressure, the smaller the angle. Preferably, the carbon nanotubes in the carbon nanotube pressed film are arranged parallel to the growth substrate. According to different rolling methods, the carbon nanotubes in the carbon nanotube rolling film have different arrangements. When rolling in the same direction, the carbon nanotubes are preferentially oriented and arranged in a fixed direction. Please refer to FIG. 5. When rolling in different directions, the carbon nanotubes are preferentially oriented and arranged in different directions. When the carbon nanotube array is vertically rolled from the top of the carbon nanotube array, the carbon nanotube pressed film is isotropic. The length of the carbon nanotubes in the carbon nanotube pressed film is greater than 50 microns. There is a certain gap between adjacent carbon nanotubes in the carbon nanotube pressed film, so that a plurality of pores are formed in the carbon nanotube pressed film, and the size of the pores is about less than 10 microns.

In step S2, the carbon nanotube film is annealed in air using a CVD tube furnace. This step is to slightly oxidize and open the closed ends of the carbon nanotubes to expose the catalyst particles inside. The laid carbon nanotube film sample is rapidly heated to 500-800° C. in an air atmosphere using a CVD tube furnace, kept heated for 10-30 minutes, and finally rapidly cooled to room temperature, preferably heated at 600° C. for 15 minutes. The use of a higher heating and cooling rate is to avoid too long heating time and uncontrollable oxidation process. When the heating temperature is lower than 500° C., the carbon nanotubes can still remain stable in the air and are not easily oxidized.

In step S3, the carbon nanotube film is treated with an inorganic acid, and the metal catalyst particles in the carbon nanotube film react with the inorganic acid to form an inorganic salt, and then the inorganic salt attached to the carbon nanotube film is washed. During the washed process, most of the inorganic salts are washed away. Generally, a mixed solution of an inorganic acid and a volatile organic solvent such as ethanol, acetone, isopropanol, etc. is used to wash the carbon nanotube film. Since the carbon nanotube film is hydrophobic and lightweight, if a volatile organic solvent is not used, the carbon nanotube film will float on the solution and cannot be immersed in the mixed solution of the inorganic acid and the volatile organic solvent. If the content of the volatile organic solvent in the mixed solution is relatively small, the carbon nanotube film cannot be completely immersed in the solution, and if the content is relatively large, the concentration of the acid will be diluted. The acid can use inorganic acids such as HCl, H₂SO₄, H₃PO₄, or one of the acids or a mixed acid of any two. During the acid treatment process, the metal catalyst particles in the carbon nanotubes react with the inorganic acid to form inorganic salts. In this embodiment, a mixed solution of 12 mol/L HCl and an equal volume of ethanol is used to immerse the carbon nanotube film in the mixed solution for 72 hours, and the metal catalyst particles in the carbon nanotubes react with hydrochloric acid to form chloride salts of the corresponding metals, such as ferric chloride.

In step S3, the carbon nanotube film is taken out and rinsed with a mixed solution of a large amount of volatile organic solvent and water, and dried at 50-80° C. In this process, most of the inorganic salts attached to the carbon nanotube film sample are washed away. In this embodiment, the carbon nanotube film sample is taken out and rinsed with a mixed solution of a large amount of ethanol and water, and dried at 60° C., and most of the chloride salts attached to the carbon nanotube film sample are washed away. The volatile organic solvent used in cleaning the carbon nanotube film is preferably the same as the volatile organic solvent used when the carbon nanotube film is acid-treated with an inorganic acid. This can avoid the introduction of other substances into the carbon nanotube film and use fewer types of solvents, which is convenient for operation.

In step S4, the carbon nanotube film is annealed to remove the inorganic salts remaining in the carbon nanotube film. Specifically, the carbon nanotube film is annealed in an atmosphere of inert gas or nitrogen using a CVD tube furnace, the temperature is controlled between 300° C. and 500° C., and the flow rate of inert gas or nitrogen is controlled between 50 and 500 sccm. Since the boiling point of inorganic salts is usually low, when annealing at a temperature higher than the boiling point of inorganic salts, the inorganic salts remaining in the carbon nanotube film or carbon nanotubes can be sublimated and carried away by the argon flow, further purifying the carbon nanotube film. In this embodiment, the carbon nanotube film is annealed in an atmosphere of argon using a CVD tube furnace, preferably at 350° C. and an argon flow rate of 100 sccm for 2 hours. The inorganic salts such as ferric chloride remaining in the carbon nanotube film are sublimated and carried away by the argon flow, further purifying the carbon nanotube film.

After being treated, the carbon nanotube film of one embodiment according to the present disclosure is tested by inductively coupled plasma mass spectrometry (ICP-MS), only 0.14 μg Fe is found in the carbon nanotube film.

It can be seen that the method to treat carbon nanotube film surface provided by the present invention can reduce the iron content in the carbon nanotube film, and of course, the content of other metal elements can also be reduced.

The method to treat carbon nanotube film surface provided by the present invention can greatly reduce the content of catalyst metal in the carbon nanotube film in a relatively simple way without destroying the structure of the carbon nanotube film, so that the carbon nanotube film is cleaner and can be applied to various fields.

It is to be understood that the above-described embodiments are intended to illustrate rather than limit the present disclosure. Variations can be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

Depending on the embodiment, certain of the steps of a method described can be removed, others can be added, and the sequence of steps can be altered. The description and the claims drawn to a method may comprise some indication in reference to certain steps. However, the indication used is only to be viewed for identification purposes and not as a suggestion as to an order for the steps.

What is claimed is:

1. A method to treat carbon nanotube film surface, the method comprising:
S1: providing a carbon nanotube film, and laying the carbon nanotube film on a surface of a substrate, wherein the carbon nanotube film comprises a plurality of catalyst particles;
S2: annealing the carbon nanotube film;
S3: making an inorganic acid mixture and treating the carbon nanotube film with the inorganic acid so that the inorganic acid reacts with the plurality of metal catalyst particles in the carbon nanotube film to generate inorganic salts; and
S4: washing the carbon nanotube film with the inorganic salts; and annealing the carbon nanotube film with the inorganic salts according to a preset temperature profile in a preset atmosphere thereby removing the inorganic salts.

2. The method of claim 1, wherein in S3, the inorganic acid mixture is made by mixing an inorganic acid in a volatile organic solvent to form the inorganic acid mixture, treating the carbon nanotube film is by immerging the carbon nanotube film in the inorganic acid mixture.

3. The method of claim 2, wherein the volatile organic solvent is selected from ethanol, acetone and isopropanol.

4. The method of claim 2, wherein the inorganic acid is selected from at least one of hydrochloric acid, sulfuric acid, and phosphoric acid.

5. The method of claim 2, wherein S4 further comprising removing the carbon nanotube film from the inorganic acid mixture, rinsing the carbon nanotube film with a mixed solution of a volatile organic solvent and water, and drying the carbon nanotube film at 50-80° C.

6. The method of claim 5, wherein the volatile organic solvent is selected from ethanol, acetone and isopropanol.

7. The method of claim 1, wherein S4 further comprising annealing the carbon nanotube film in a CVD tube furnace, and the preset temperature profile is heating the carbon nanotube film to a temperature ranged from 500° C. to 800° C. for 10-30 minutes, and then cooling to a room temperature.

8. The method of claim 1, wherein S4 further comprising annealing the carbon nanotube film in CVD tube furnace, and the preset temperature profile is heating the carbon nanotube film to 300-500° C., and the present atmosphere is an atmosphere of flowing inert gas or flowing nitrogen with a flow rate controlled between 50-500 sccm.

9. The method of claim 1, wherein after laying the carbon nanotube film on the surface of the substrate, in S3 the inorganic acid mixture is made with a volatile organic solvent that shrink the carbon nanotube film, and S3 further comprising drying the carbon nanotube film is at 50-80° C.

10. The method of claim 1, wherein in S1, a super-aligned carbon nanotube film, a carbon nanotube pressed film or a carbon nanotube flocculation film is provided as the carbon nanotube film.

11. The method of claim 10, wherein the super-aligned carbon nanotube film is a single-layer, super-aligned carbon nanotube film comprising a plurality of carbon nanotubes oriented substantially in a same direction and arranged parallel to a surface of the super-aligned carbon nanotube film, and the plurality of carbon nanotubes is connected end to end by van der Waals forces between the plurality of carbon nanotubes.
